(19) United States
(12) Patent Application Publication
(10) Pub. No.: US 2013/0040448 A1
(43) Pub. Date: Feb. 14, 2013

(54) METHODS OF FORMING METAL OR METAL NITRIDE PATTERNS AND METHODS OF MANUFACTURING SEMICONDUCTOR DEVICES

(71) Applicants: Joo-Hyung Yang, Suwon-si (KR); Yool Kang, Yongin-si (KR); Hyung-Rae Lee, Hwaseong-si (KR); Kyu-Sik Shin, Suwon-si (KR); Jae-ho Kim, Yongin-si (KR); Dong-Jun Lee, Seoul (KR)

(72) Inventors: Joo-Hyung Yang, Suwon-si (KR); Yool Kang, Yongin-si (KR); Hyung-Rae Lee, Hwaseong-si (KR); Kyu-Sik Shin, Suwon-si (KR); Jae-ho Kim, Yongin-si (KR); Dong-Jun Lee, Seoul (KR)

(73) Assignee: SAMSUNG ELECTRONICS CO., LTD., Suwon-si (KR)

(21) Appl. No.: 13/570,812

(22) Filed: Aug. 9, 2012

(30) Foreign Application Priority Data
Aug. 11, 2011 (KR) 10-2011-0080235

(51) Int. Cl. H01L 21/312; H01L 21/336

(52) U.S. Cl. 438/585; 438/694; 257/E21.409; 257/E21.259

(57) ABSTRACT

In a method of forming a metal or metal nitride pattern, a metal or metal nitride layer is formed on a substrate, and a photoresist pattern is formed on the metal or metal nitride layer. An over-coating composition is coated on the metal or metal nitride layer and on the photoresist pattern to form a capping layer on the photoresist pattern. The over-coating composition includes a polymer having amine groups as a side chain or a branch and a solvent. A remaining portion of the over-coating composition is removed by washing with a hydrophilic solution. The metal or metal nitride layer is partially removed using the capping layer and the photoresist pattern as an etching mask.

### CROSS-REFERENCE TO RELATED APPLICATIONS

This application claims priority under 35 U.S.C. §119 to Korean Patent Application No. 2011-0080235, filed on Aug. 11, 2011, in the Korean Intellectual Property Office (KIPO), the entire disclosure of which is incorporated by reference herein.

### BACKGROUND

1. Field

Example embodiments relate to methods of forming metal (or metal nitride) patterns and methods of manufacturing semiconductor devices.

2. Description of the Related Art

To form metal wiring or a metal gate of a semiconductor device, a photoresist pattern may be formed on a metal layer, and the metal layer may be partially etched to form a metal pattern using the photoresist pattern as an etching mask.

As the degree of integration of the semiconductor device has been increased, the line-width or a critical dimension of the metal pattern (including, e.g., the metal wiring or the metal gate) have been decreased. Thus, photoresist residues may remain on the metal layer due to a resolution limit during, e.g., an exposure process in the formation of the photoresist pattern. Further, the photoresist pattern may be damaged during the etching process in the formation of the metal pattern.

### SUMMARY

Example embodiments provide methods of forming a metal pattern having a minute line-width.

Additional exemplary embodiments provide methods of manufacturing a semiconductor device including a metal pattern of a minute line-width.

According to example embodiments, a metal or metal nitride layer is formed on a substrate. A photoresist pattern is formed on the metal or metal nitride layer. An over-coating composition is coated on the metal or metal nitride layer and on the photoresist pattern to form a capping layer on the photoresist pattern. The over-coating composition includes a solvent and a polymer having amine groups as a side chain or as a branch. A remaining portion of the over-coating composition is removed by washing with a hydrophilic solution. The metal or metal nitride layer is partially removed using the capping layer and the photoresist pattern as an etching mask.

In example embodiments, the polymer included in the over-coating composition may be produced by a single-polymerization or by a co-polymerization of at least one monomer including vinyl pyrrolidone, vinyl caprolactam, vinyl imidazole, vinyl piperidine or vinyl pyrrolidine.

In example embodiments, in the formation of the photoresist pattern, a photoresist layer may be formed of a photosensitive polymer on the metal or metal nitride layer. The photoresist layer may be partially removed by an exposure process, though a photoresist residue may remain on a portion of the metal or metal nitride layer not covered by the resulting photoresist pattern.

In example embodiments, the photosensitive polymer may include carboxylic groups as a side chain or as a branch.

In example embodiments, the polymer of the over-coating composition and the photosensitive polymer may be combined with each other by forming a hydrogen bond or by a dipole interaction.

In example embodiments, the photoresist residue may be removed, together with the over-coating composition, by the hydrophilic solution.

In example embodiments, the over-coating composition may further include a pH-adjusting agent, and the pH value of the over-coating composition may be within a range of about 4 to about 6.

In example embodiments, the polymer of the over-coating composition and the photosensitive polymer may be combined with each other by forming an ionic bond.

In example embodiments, the metal or metal nitride layer may be formed of titanium, titanium nitride, aluminum, aluminum nitride, tungsten or tungsten nitride.

In example embodiments, the hydrophilic solution may include water or alcohol.

In example embodiments, the metal or metal nitride layer may be partially removed by a wet-etching process using a hydrogen peroxide solution.

In example embodiments, the over-coating composition may further include a thermal acid generator (TAG).

In example embodiments, a baking process may also be performed on the capping layer.

According to example embodiments, there is provided a method of manufacturing a semiconductor device. In the method, a gate pattern is formed on a substrate. Impurity regions are formed at upper portions of the substrate adjacent to the gate pattern. An insulating interlayer covering the substrate and the gate pattern may be formed. Plugs are formed through the insulating interlayer and are electrically connected to the impurity regions. A metal or metal nitride layer is formed on the insulating interlayer and the plugs, and a photoresist pattern is formed on the metal or metal nitride layer. An over-coating composition is coated on the metal or metal nitride layer and on the photoresist pattern to form a capping layer on the photoresist pattern. The over-coating composition includes a solvent and a polymer having amine groups as a side chain or as a branch and. A remaining portion of the over-coating composition is removed by washing with a hydrophilic solution. The metal or metal nitride layer is partially removed using the capping layer and the photoresist pattern as an etching mask to form metal wirings electrically connected to the plugs.

In example embodiments, in the formation of the gate pattern, a gate-insulation layer and a gat-electrode layer may be sequentially formed on the substrate. A photoresist pattern may be formed on the gate-electrode layer. An over-coating composition may be coated on the gate-electrode layer and on the photoresist pattern to form a capping layer on the photoresist pattern. The over-coating composition may include a polymer and a solvent. The polymer may have amine groups as a side chain or a branch. A remaining portion of the over-coating composition may be removed by washing with a hydrophilic solution. The gate-electrode layer may be partially removed using the capping layer and the photoresist pattern as an etching mask to form a gate electrode. Meanwhile, the gate-insulation layer may be partially removed using the gate electrode as an etching mask to form a gate-insulation layer pattern.

According to example embodiments, a photoresist pattern may be formed on a metal or metal nitride layer, and an over-coating composition may then be coated on a surface of the photoresist pattern to form a capping layer on. The capping layer may protect the photoresist pattern to prevent damage to the photoresist pattern when etching the metal or metal nitride layer. After forming the capping layer, the remaining over-coating composition may be removed or cleaned using a hydrophilic solution. Photoresist residues remaining on the metal or metal nitride layer may be removed or cleaned together with the over-coating composition.

### BRIEF DESCRIPTION OF THE DRAWINGS

Example embodiments will be more clearly understood from the following detailed description taken in conjunction with the accompanying drawings. FIGS. 1 to 25 represent non-limiting, example embodiments, as described herein.

FIGS. 1 and 7 are cross-sectional views illustrating a method of forming a metal pattern in accordance with example embodiments;

FIGS. 8 and 15 are cross-sectional views illustrating a method of forming metal wiring in accordance with example embodiments;

FIGS. 16 to 23 are cross-sectional views illustrating a method of manufacturing a semiconductor device in accordance with example embodiments; and

FIGS. 24 to 25 are transmission-electron-microscope (TEM) images showing metal patterns formed by methods in accordance with the Example and the Comparative Example, respectively.

It should be noted that these figures are intended to illustrate the general characteristics of methods, structures and/or materials utilized in certain example embodiments and to supplement the written description provided below. These drawings are not, however, to scale and may not precisely reflect the precise structural or performance characteristics of any given embodiment and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature

### DESCRIPTION OF EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete and to fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms, first, second, third, fourth, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the present inventive concept.

Spatially relative terms, such as “beneath,” “below,” “lower,” “above,” “upper” and the like, may be used herein for ease of description to describe the relationship of one element or feature to another element(s) or feature(s), as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms, “a,” “an” and “the”, are intended to include the plural forms, as well, unless the context clearly indicates otherwise. It will be further understood that the terms, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature; and their shapes are not intended to illustrate the actual shape of a region of a device, nor are they intended to limit the scope of the present inventive concept.

Unless otherwise defined, all terms (including technical and scientific terms) used herein have the same meaning as is commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

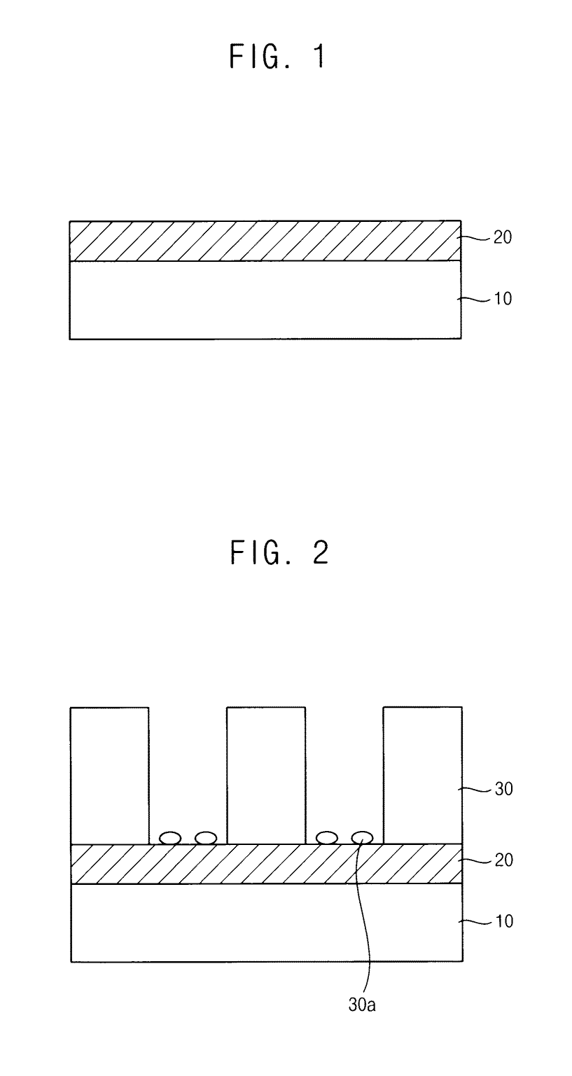

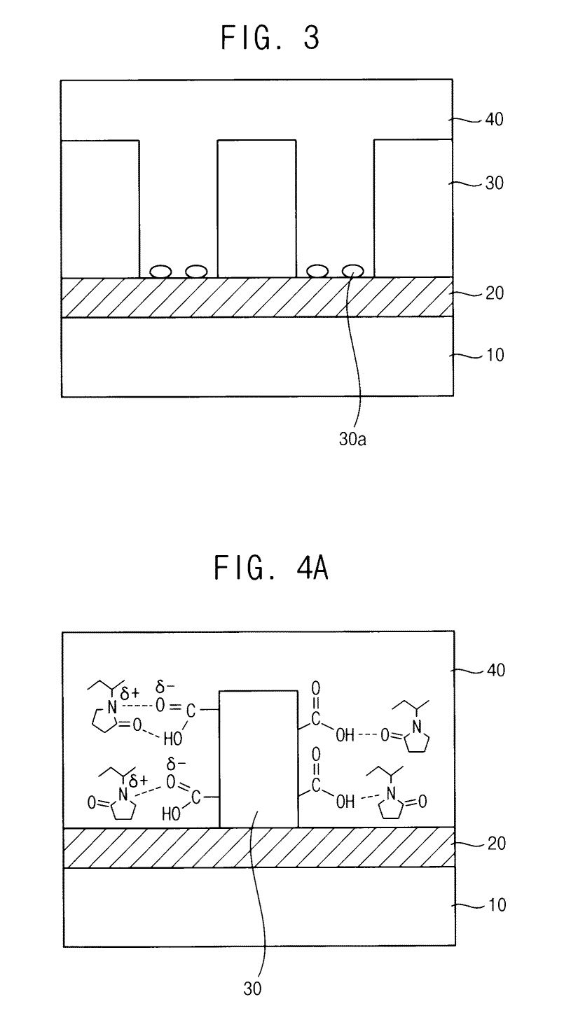

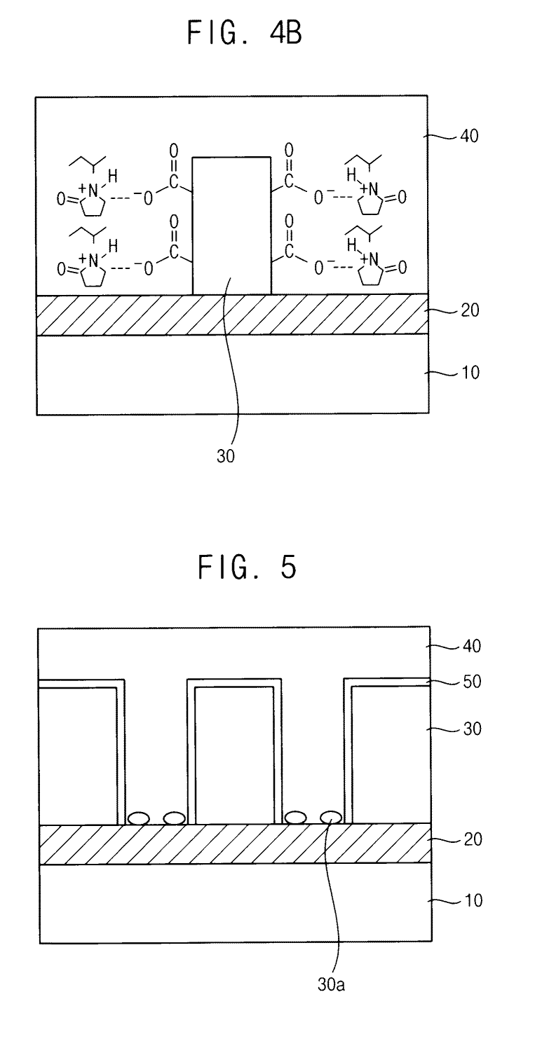

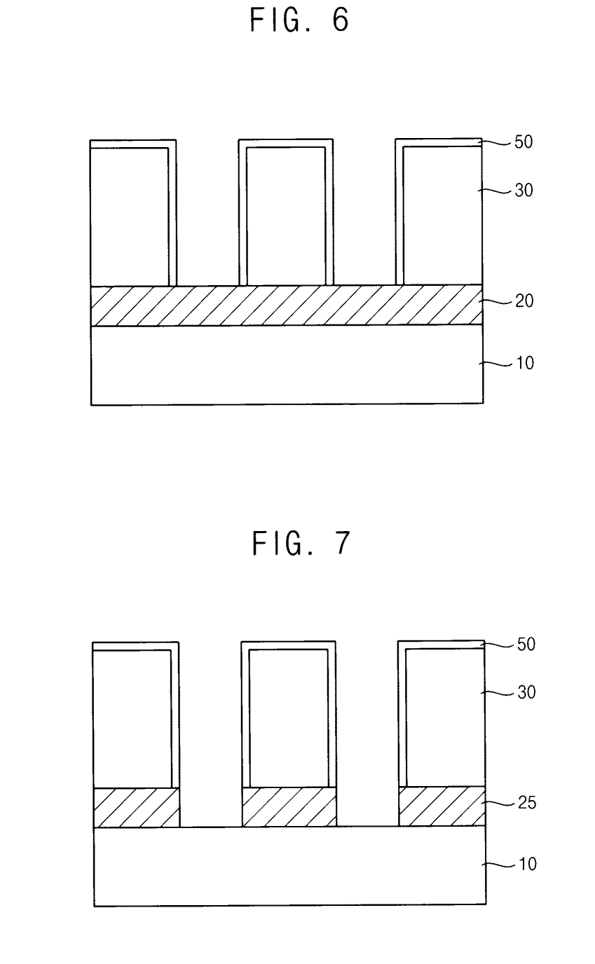

A method of forming a metal pattern in accordance with example embodiments is illustrated via cross-sectional views in FIGS. 1 and 7.

Referring to FIG. 1, a metal or metal nitride layer 20 may be formed on a substrate 10.

The substrate 10 may include a semiconductor substrate. For example, the substrate 10 may include a silicon substrate, a germanium substrate, a silicon-germanium substrate, a silicon-on-insulator (SOI) substrate, a germanium-on-insulator (GOI) substrate, etc. Further, the substrate 10 may include lower structures (not illustrated), such as a transistor, a plug, a metal contact, an insulation pattern, etc., thereon.

The metal or metal nitride layer 20 may be formed of a metal and/or a metal nitride deposited by, e.g., a sputtering process, a physical-vapor-deposition (PVD) process, an atomic-layer-deposition (ALD) process, etc. For example, the metal or metal nitride layer 20 may be formed of any of titanium, titanium nitride, aluminum, aluminum nitride, tungsten, tungsten nitride, etc.

Referring to FIG. 2, a photoresist pattern 30 may be formed on the metal or metal nitride layer 20 such that the metal or metal nitride layer 20 may be partially exposed by the photoresist pattern 30. Moreover, a plurality of the photoresist patterns 30 may be formed on the metal or metal nitride layer 20 to form a plurality of metal patterns 25 (see FIG. 7).

In example embodiments, a photoresist layer may be formed on the metal or metal nitride layer 20, and the photoresist layer may be partially removed by, e.g., exposure and developing processes to form the photoresist pattern 30.

The photoresist layer may be formed of a photoresist composition that may include a photosensitive polymer, a photoacid generator, a solvent, etc. The photoresist layer may be formed by, e.g., any of a spin-coating process, a spray-coating process, a dip-coating process, etc. The photoresist composition may include, but is not limited to, a chemically amplified photoresist material. In example embodiments, the photosensitive polymer contained in the photoresist composition may include carboxylic groups as a side chain or as a branch.

As the line-width of the metal pattern 25 decreases, the distance between adjacent photoresist patterns 30 may be also decreased. Due to a resolution limit of the exposure apparatus, however, a photoresist residue 30a generated from the photoresist layer may remain on the metal or metal nitride layer 20, which may be etched by a subsequent process.

Referring to FIG. 3, an over-coating layer 40 covering the photoresist pattern 30 and the photoresist residue 30a may be formed on the metal or metal nitride layer 20. In example embodiments, the over-coating layer 40 may be formed using an over-coating composition via a spin-on method.

The over-coating composition may include a solvent and a polymer that may be produced by a single-polymerization or a co-polymerization of monomers having amine groups as a side chain or as a branch. In example embodiments, non-limiting examples of the monomers may include vinyl pyrrolidone, which is represented by Chemical Formula 1; vinyl caprolactam, which is represented by Chemical Formula 2; vinyl imidazole, which is represented by Chemical Formula 3; vinyl piperidine, which is represented by Chemical Formula 4; vinyl pyrrolidine, which is represented by Chemical Formula 5, etc. The side chain or the branch of the monomer may include additional oxygen or nitrogen atoms (that may form a hydrogen bond) in addition to a nitrogen atom of the amine group, as seen in vinyl pyrrolidone, vinyl caprolactam and vinyl imidazole.

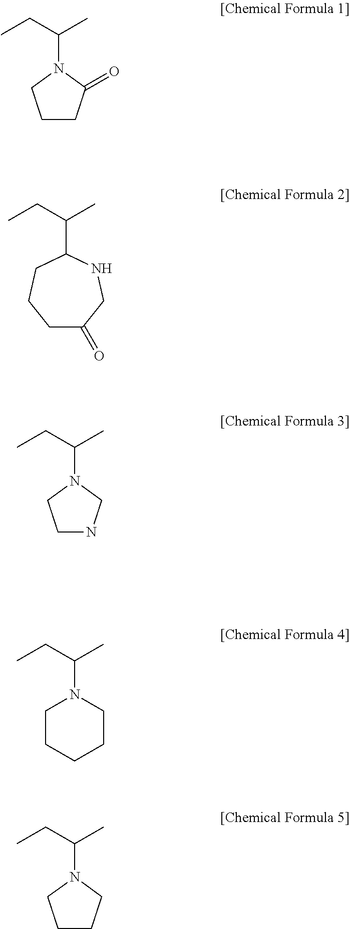

In example embodiments, the polymer may have a weight-average molecular weight from about 1,000 to about 100,000. When the weight-average molecular weight of the polymer is less than about 1,000, a capping layer 50 (see FIG. 5) may not be uniformly formed on the photoresist pattern 30. On the other hand, when the weight-average molecular weight of the polymer exceeds about 100,000, the over-coating composition may not be easily removed by subsequent processes.

In example embodiments, the solvent may include any hydrophilic solvent than may dissolve the polymer.

The over-coating composition may be weakly acidic. For example, the over-coating composition may have a pH value in a range of about 4 to about 6. When the pH value of the over-coating composition is less than about 4, the metal or metal nitride layer 20 may be damaged, and ionic bonds at an interface between the photoresist pattern 30 and the over-coating layer 40 may not be easily formed (refer to FIG. 4B). On the other hand, when the pH value of the over-coating composition exceeds about 6, the ionic bonds at the interface between the photoresist pattern 30 and the over-coating layer 40 may not be easily formed. In example embodiments, a suitable pH-adjusting agent for controlling the pH value of the over-coating composition within the above-mentioned range may be added to the over-coating composition.

In example embodiments, the over-coating composition may further include a thermal acid generator (TAG). For example, the TAG may include sulfonic acid-ester and derivatives thereof that may generate sulfonic acid by heat.

FIGS. 4A and 4B illustrate the formation of bonds at the interface between the over-coating layer 40 and the photoresist pattern 30. A case where the over-coating composition includes polyvinyl pyrrolidone as the polymer and where the photosensitive polymer of the photoresist pattern 30 includes carboxylic groups as the side chain or the branch is illustrated in FIGS. 4A and 4B.

Referring to FIG. 4A, inclusion of polyvinyl pyrrolidone in the over-coating composition and exposure of the carboxylic group at an outer surface of the photoresist pattern 30 may form a hydrogen bond.

The hydrogen bond may be formed, for example, between a nitrogen atom of a pyrrolidone group and a hydrogen atom of the carboxylic group or between an oxygen atom of a ketone group in the pyrrolidone group and the hydrogen atom of the carboxylic group.

Additionally, the pyrrolidone group and the carboxylic group may become adjacent to each other at the interface between the over-coating layer 40 and the photoresist pattern 30 to generate a dipole interaction. For example, a partial positive charge may be induced at the nitrogen atom of the pyrrolidone group, and a partial negative charge may be induced at the oxygen atom of the carboxylic group. Accordingly, a weak bond between the nitrogen atom and the oxygen atom may be formed by the dipole interaction.

As illustrated in FIG. 5, the capping layer 50 may be formed on the outer surface of the photoresist pattern 30 and in the over-coating layer 40 by the hydrogen bond, the dipole interaction or a combination thereof.

Referring to FIG. 4B, the ionic bonds may be formed at the interface of the over-coating layer 40 and the photoresist pattern 30. For example, the pH value of the over-coating composition may be adjusted to form the ionic bonds.

In example embodiments, the pH value of the over-coating composition may be adjusted in a range of about 4 to about 6. In this case, the carboxylic group may be more acidic than the over-coating composition, and thus proton (H+) may dissociated from the carboxylic group to form a carboxylate anion. The nitrogen atom of the pyrrolidone group may accept the proton to be converted into a cation. Consequently, the ionic bond may be formed between the anion and the cation such that the capping layer 50 may be formed on the surface of the outer surface photoresist pattern 30. The ionic bond may have a bonding force greater than those of the hydrogen bond and the dipole interaction, and thus adhesion of the capping layer 50 to the photoresist pattern 30 may be enhanced.

According to the above-described mechanism, the photoresist residue 30a may be combined with the polymer of the over-coating composition by the hydrogen bond, the dipole interaction or the ionic bond.

Referring to FIG. 6, a remnant of the over-coating layer 40 that may not be changed into the capping layer 50 may be removed using a cleaning solution. The photoresist residue 30a combined with the polymer of the over-coating composition may also be removed together with the over-coating layer 40.

In example embodiments, the cleaning solution may include a hydrophilic solution (for example, water or alcohol).

Generally, an ashing process and/or a cleaning process may be utilized to remove the photoresist residue remaining on the metal or metal nitride layer 20. In the ashing process and/or in the cleaning process, active species having high reactivity may be used to damage or transform the metal or metal nitride layer 20. Thus, an additional process for forming a protection layer on the metal or metal nitride layer 20 may be required. However, the metal or metal nitride layer 20 may not be completely protected from being damaged by the active species. Further, the photoresist pattern 30 may be still damaged.

In example embodiments, the photoresist residue 30a may be combined with the polymer of the over-coating layer 40 so as to be easily removed together with the over-coating layer 40 using a hydrophilic solution with a low reactivity, such as water or alcohol. Consequently, the metal or metal nitride layer 20 may be protected from being damaged or transformed even without the additional protection layer. Further, the photoresist pattern 30 may be preserved from damage because the ashing or cleaning process (for removing the photoresist residue 30a) may be omitted.

In example embodiments, a baking process may be further performed on the capping layer 50 after removing the over-coating layer 40 and the photoresist residue 30a. Acids may be generated from the TAG contained in the capping layer 50 during the baking process, and the acids may serve as a catalyst to induce a cross-linking reaction of polymers contained in the capping layer 50. Thus, the capping layer 50 may be hardened or cured to have an improved stability.

Referring to FIG. 7, the metal or metal nitride layer 20 (shown in FIG. 6) may be partially removed using the photoresist pattern 30 having the capping layer 50 thereon as an etching mask to form the metal pattern 25.

In example embodiments, the metal or metal nitride layer 20 may be etched by a wet etching process in which an etching solution including hydrogen peroxide and an acidic solution may be used. The acidic solution may include hydrochloric acid, nitric acid, sulfuric acid, etc.

During the wet etching process, the photoresist pattern 30 may be protected by the capping layer 50. Thus, the photoresist pattern 30 may not be damaged by the etching solution. Therefore, a metal pattern 25 having uniform line width and/or surface profile may be obtained.

The capping layer 50 and the photoresist pattern 30 may be removed by, e.g., an ashing process and/or a strip process after forming the metal pattern 25.

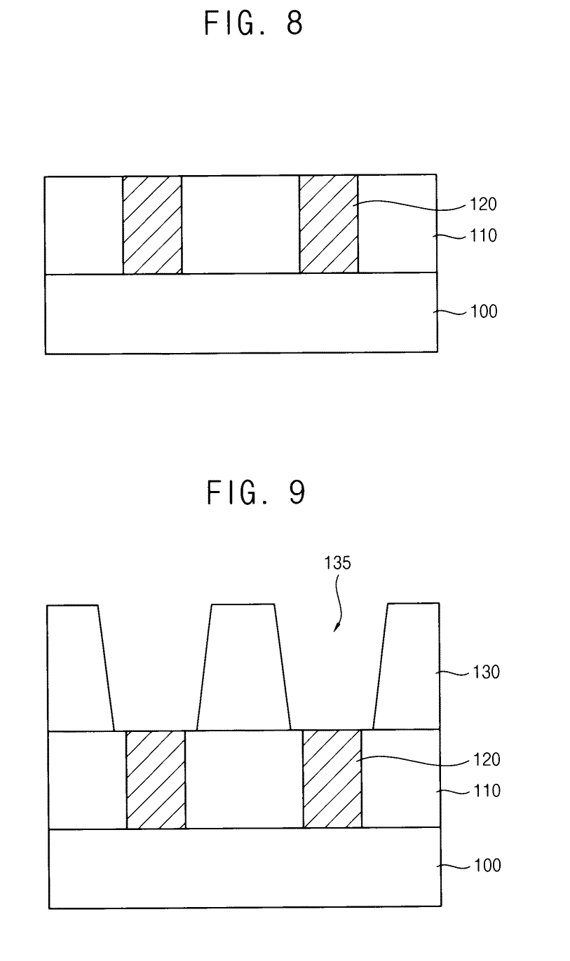

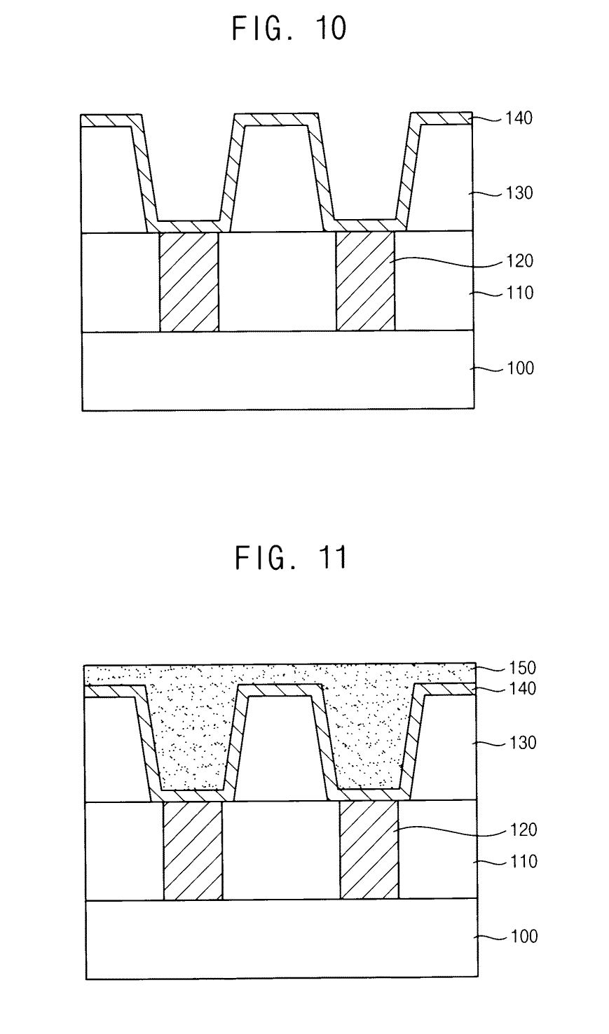

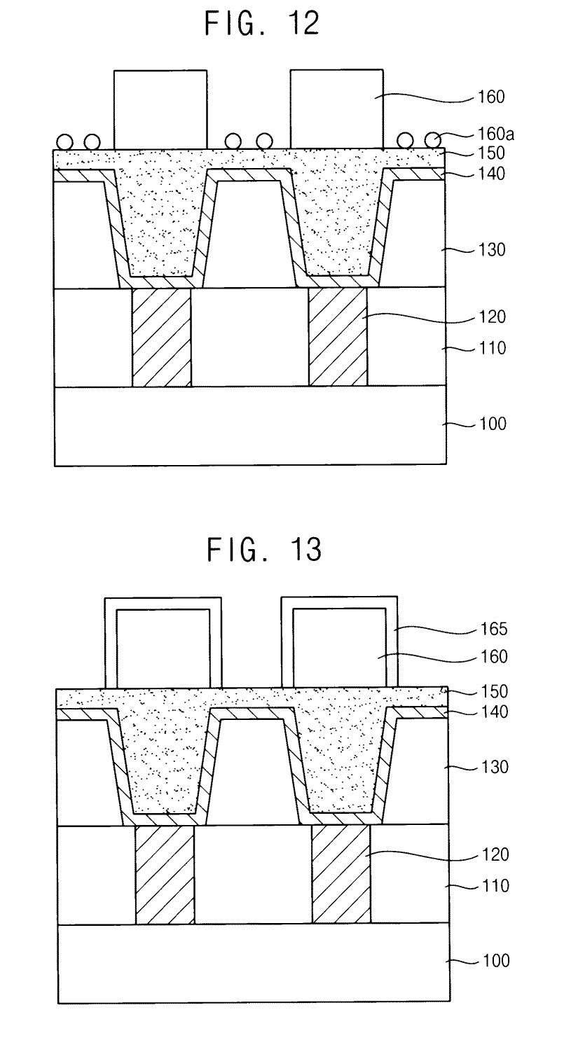

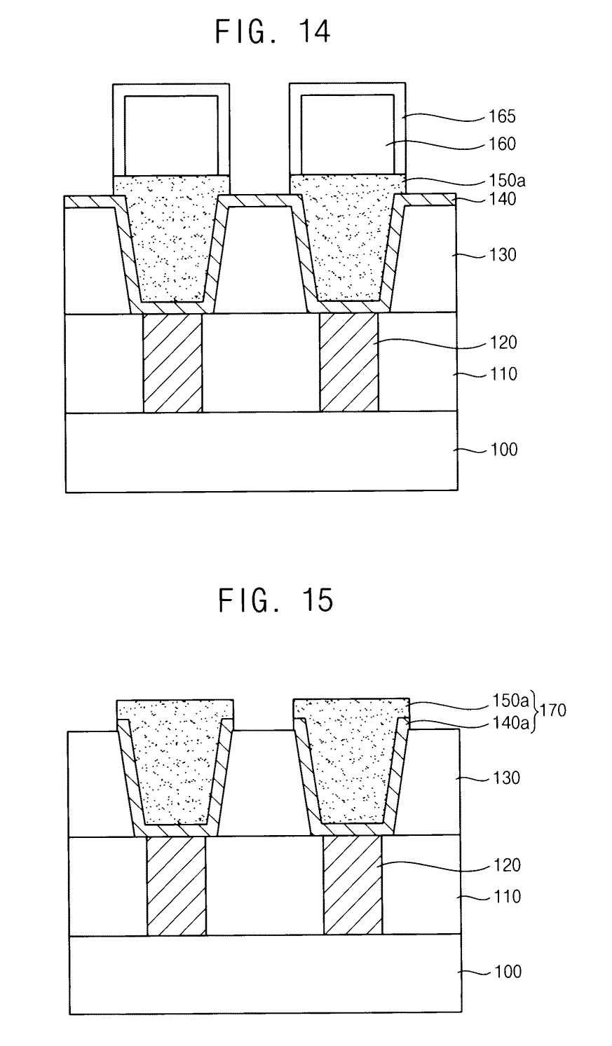

FIGS. 8 and 15 are cross-sectional views illustrating a method of forming metal wiring in accordance with example embodiments.

Referring to FIG. 8, a first insulating interlayer 110 may be formed on a substrate 100 and a plug 120 may be formed through the first insulating interlayer 110 to be in contact with the substrate 100.

The substrate 100 may include a semiconductor substrate. For example, the substrate 100 may include any of a silicon substrate, a germanium substrate, a silicon-germanium substrate, a silicon-on-insulator (SOI) substrate, a germanium-on-insulator (GOI) substrate, etc. The substrate 100 may include lower structures (not illustrated) such as a transistor, a bit line, an insulation pattern, etc., thereon.

The first insulating interlayer 110 may be formed of silicon oxide deposited by, e.g., any of a chemical-vapor-deposition (CVD) process, a plasma-enhanced chemical-vapor-deposition (PECVD) process, a spin-coating process, a high-density-plasma chemical-vapor-deposition (HDP-CVD) process, a low-pressure chemical-vapor-deposition (LPCVD) process, etc.

The first insulating interlayer 110 may be partially removed by, e.g., a photolithography process to form a contact hole (not illustrated) exposing a top surface of the substrate 100. In example embodiments, the substrate 100 may include a conductive region (not illustrated), such as an impurity region, and the conductive region may be exposed by the contact hole (which is then filled by plug 120). A conductive layer sufficiently filling the contact hole may be formed on the substrate 100 and the first insulating interlayer 110. The conductive layer may be planarized until a top surface of the insulating interlayer 110 is exposed to form the plug 120. In example embodiments, a plurality of the plugs 120 may be formed on the substrate 100.

Referring to FIG. 9, a second insulating interlayer 130 may be formed on the first insulating interlayer 110 and the plug 120. The second insulating interlayer 130 may be partially etched to form an opening 135 exposing the plug 120.

The second insulating interlayer 130 may be formed of an insulating material, e.g., silicon oxide deposited by, e.g., a CVD process, a PECVD process, or an LPCVD process. The second insulating interlayer 130 may be formed of the same material as that of the first insulating interlayer 110.

Referring to FIG. 10, a barrier layer 140 may be formed on the second insulating interlayer 130 and on a sidewall and a bottom of the opening 135 (on the plug 120).

The barrier layer 140 may prevent metal components of a metal or metal nitride layer 150 (see FIG. 11) from being diffused into the first and second insulating interlayers 110 and 130. The barrier layer 140 may be formed of a material that may have good adhesion, low electrical conductivity, high thermal or mechanical stability, etc. In example embodiments, the barrier layer 140 may be formed of tantalum or tantalum nitride deposited by, e.g., any of a CVD process, a sputtering process, an ALD process, a PVD process, etc.

Referring to FIG. 11, a metal or metal nitride layer 150 may be formed on the barrier layer 140. In example embodiments, the metal or metal nitride layer 150 may be formed of titanium or titanium nitride deposited by, e.g., any of a CVD process, a sputtering process, a PVD process, etc.

Referring to FIG. 12, a process substantially the same as or similar to that illustrated with reference to FIG. 2 may be performed to form a photoresist pattern 160 on the metal or metal nitride layer 150. Photoresist residue 160a may remain on a portion of the metal or metal nitride layer 150 not covered by the photoresist pattern 160.

Referring to FIG. 13, processes substantially the same as or similar to those illustrated with reference to FIGS. 3 to 6 may be performed to form a capping layer 165 on a surface of the photoresist pattern 160.

Specifically, an over-coating composition may be coated on the metal or metal nitride layer 150 by a spin-on method to form an over-coating layer (not illustrated) covering the photoresist pattern 160 and the photoresist residue 160a. The capping layer 165 may be formed on the surface of the photoresist pattern 160 by an interaction or a bonding of polymers at an interface between the over-coating layer and the photoresist pattern 160. A portion of the over-coating layer not changed into the capping layer 165 may be removed using a hydrophilic solution. The photoresist residue 160a may be also removed together with the over-coating layer.

Referring to FIG. 14, the metal or metal nitride layer 150 (shown in FIG. 13) may be partially removed using the photoresist pattern 160 and the capping layer 165 as an etching mask to form a metal pattern 150a. In example embodiments, the metal or metal nitride layer 150 may be etched by a wet etching process using a hydrogen peroxide solution as the etching solution.

The barrier layer 140 may be partially removed using the photoresist pattern 160, the capping layer 165 and the metal pattern 150a (all shown in FIG. 14) as an etching mask to form a barrier layer pattern 140a (shown in FIG. 15). Accordingly, metal wiring 170 including the metal pattern 150a and the barrier layer pattern 140a may be obtained. The metal wiring 170 may be electrically connected to the plug 120.

In one example embodiment, the metal or metal nitride layer 150 and the barrier layer 140 may be simultaneously etched. In this case, the etching solution may include the hydrogen peroxide solution and an acid (e.g., any of hydrochloric acid, nitric acid, sulfuric acid, etc.).

The photoresist pattern 160 and the capping layer 165 may be removed by, e.g., an ashing process and/or a strip process.

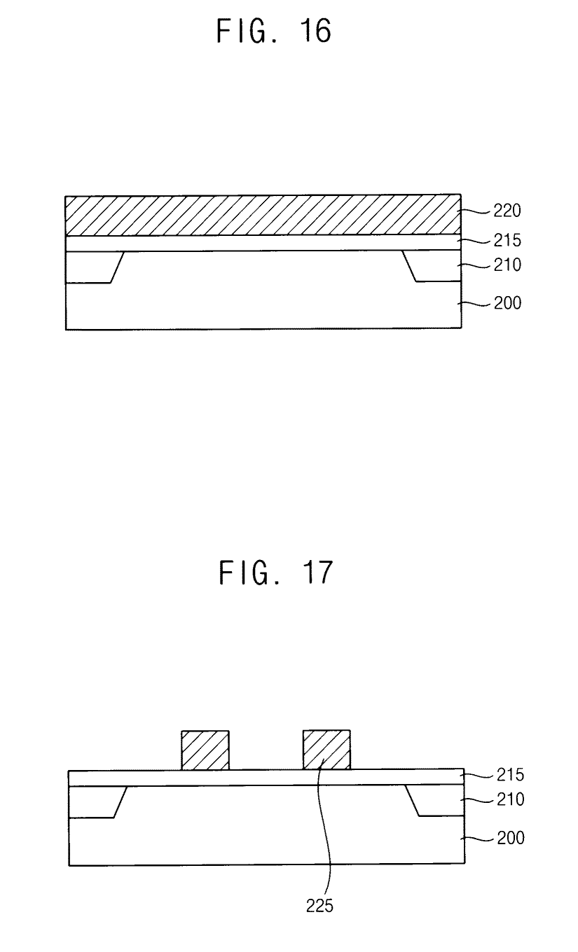

FIGS. 16 to 23 are cross-sectional views illustrating a method of manufacturing a semiconductor device in accordance with example embodiments.

Referring to FIG. 16, a gate insulation layer 215 and a gate electrode layer 220 may be sequentially formed on a substrate 200.

The substrate 200 may include a semiconductor substrate (for example, a single-crystalline substrate). An isolation layer 210 may be formed on the substrate 200 by a shallow-trench-isolation (STI) process to define an active region and a field region.

The gate insulation layer 215 may be formed of a metal oxide or a metal oxynitride having a high dielectric constant. For example, the gate insulation layer 215 may be formed of any of hafnium oxide, hafnium silicon oxide, zirconium oxide, zirconium silicon oxide, hafnium oxynitride, hafnium silicon oxynitride, zirconium oxynitride, zirconium silicon oxynitride, aluminum oxide, hafnium aluminum oxide, lanthanum oxide, hafnium lanthanum oxide, zirconium aluminum oxide, aluminum oxynitride, hafnium aluminum oxynitride, lanthanum oxynitride, hafnium lanthanum oxynitride, zirconium aluminum oxynitride, etc. These may be used alone or in a mixture thereof. Alternatively, the gate insulation layer 215 may be formed by performing a thermal oxidation process on a top surface of the substrate 200.

The gate electrode layer 220 may be formed of a metal or a metal nitride by, e.g., a sputtering process, an ALD process, a PVD process, etc. In example embodiments, the gate electrode layer 220 may be formed of titanium or titanium nitride.

Referring to FIG. 17, processes substantially the same as or similar to those illustrated with reference to FIGS. 2 to 7 may be performed so that the gate electrode layer 220 may be partially etched to form a plurality of gate electrodes 225.

The gate insulation layer 215, shown in FIG. 17, may be partially etched using the gate electrode 225 as an etching mask to form a gate insulation layer pattern 215a, as shown in FIG. 18. Accordingly, a plurality of gate patterns 230, each of which may include the gate insulation layer pattern 215a and the gate electrode 225 sequentially stacked on the substrate 200, may be obtained.

In one example embodiment, a spacer layer (not illustrated) covering the gate patterns 230 may be formed on the substrate 200. The spacer layer may be anisotropically etched to form a spacer (not illustrated) on a sidewall of the gate pattern 230.

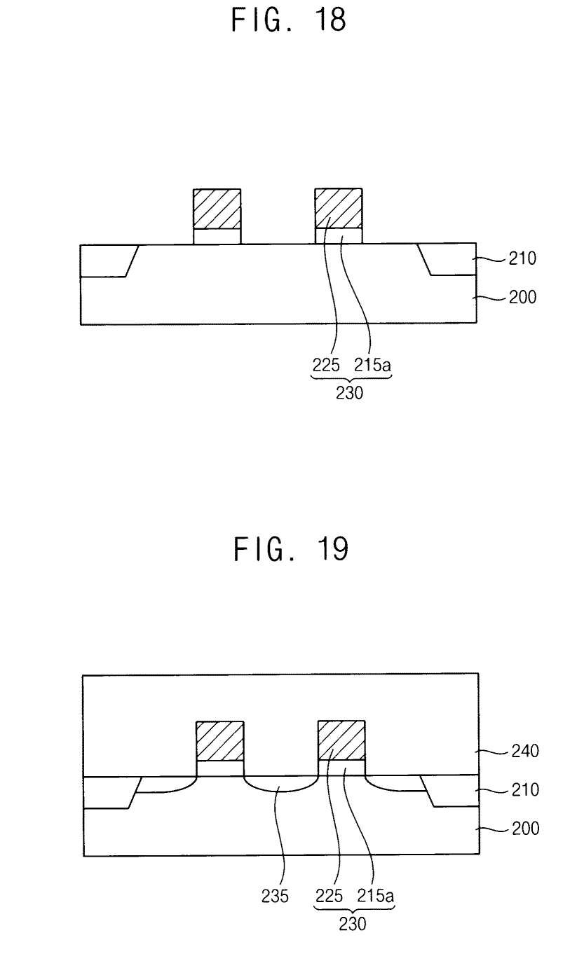

Referring to FIG. 19, impurity regions 235 may be formed at upper portions of the substrate 200 adjacent to the gate patterns 230. The impurity regions 235 may be formed by an ion implantation process using the gate pattern 230 as an ion-implantation mask. The gate pattern 230 and the impurity regions 235 may define a transistor.

A first insulating interlayer 240 covering the transistor may be formed on the substrate 200. The first insulating interlayer 240 may be formed of silicon oxide deposited by a CVD process, a PECVD process, an LPCVD process, etc.

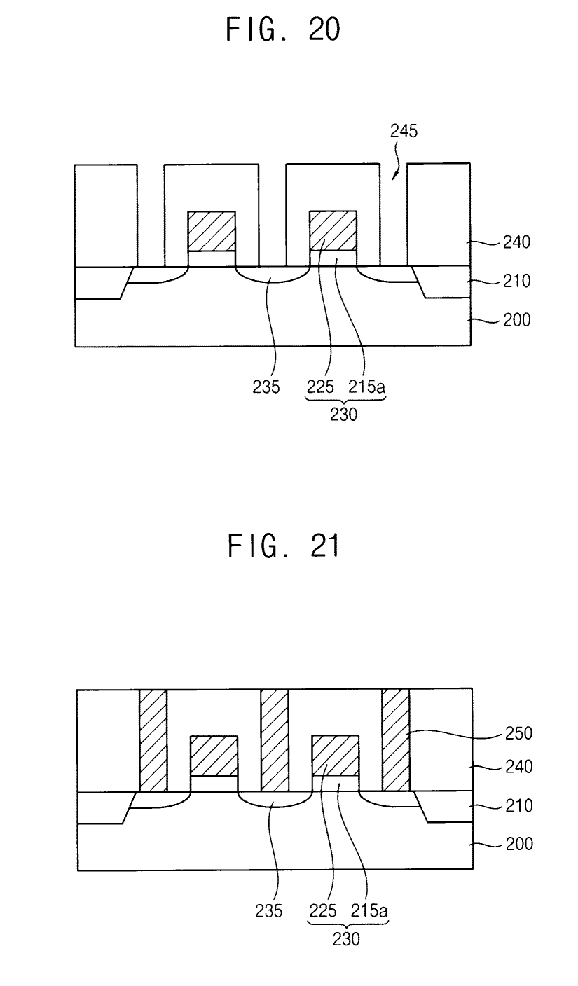

Referring to FIG. 20, the first insulating interlayer 240 may be partially etched to form contact holes 245 exposing the impurity regions 235.

Referring to FIG. 21, a conductive layer may be formed on the first insulating interlayer 240 and the impurity regions 235. The conductive layer may be planarized until a top surface of the first insulating interlayer 240 is exposed to form plugs 250 filling the contact holes 245.

The conductive layer may be formed of a metal, e.g., any of tungsten, aluminum, tantalum, ruthenium, platinum, iridium, etc. The conductive layer may be obtained by, e.g., a sputtering process, a PVD process, an ALD process, etc. The planarization process may include a chemical mechanical polishing (CMP) process and/or an etch-back process.

In one example embodiment, a metal silicide pattern (not illustrated) may be further formed on the impurity region 235 prior to forming the plug 250 to reduce contact resistance.

Referring to FIG. 22, a metal or metal nitride layer 260 may be formed on the first insulating interlayer 240 and the plugs 250. The metal or metal nitride layer 260 may be formed of a metal and/or a metal nitride—for example, titanium, titanium nitride, tungsten, or aluminum. The metal or metal nitride layer 260 may be obtained by any of a sputtering process, a PVD process, an ALD process, etc.

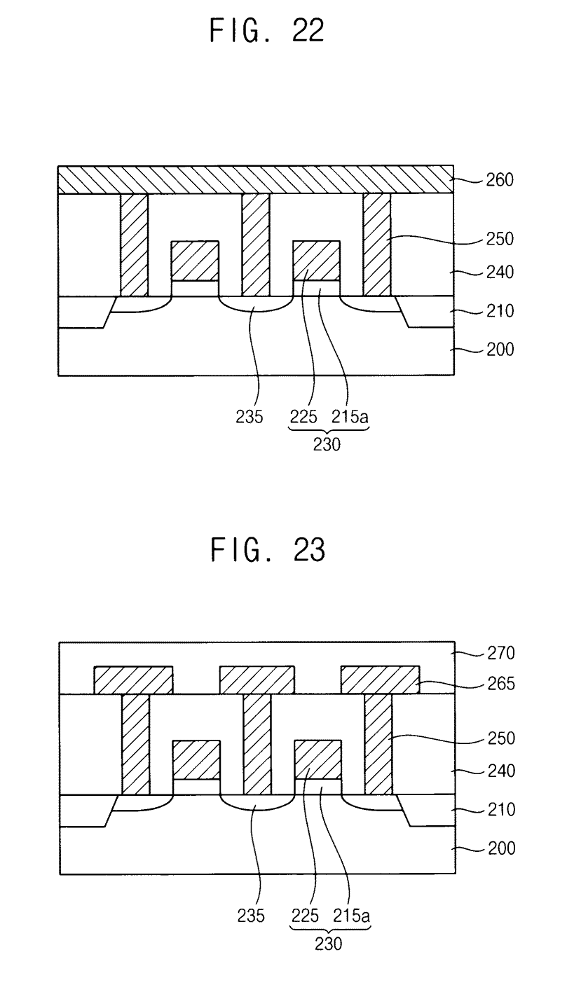

Referring to FIG. 23, processes substantially the same as or similar to those illustrated with reference to FIGS. 2 to 7 may be performed. Accordingly, the metal or metal nitride layer 260 may be partially removed to form metal wirings 265 each of which may be electrically connected to the plug 250.

A second insulating interlayer 270 covering the metal wirings 265 may be formed on the first insulating interlayer 240. In some example embodiments, additional structures (not illustrated) including, e.g., a pad, a memory unit, etc., may be formed in electrical connection to the metal wirings 265.

Hereinafter, example embodiments of the present inventive concepts will be described in more detail by an Example and a Comparative Example.

### Example

A metal nitride layer having a thickness of about 1000 Å was formed on a silicon wafer using titanium nitride. A photoresist layer was formed on the metal nitride layer using a commercially available photoresist composition (epoxy novolac manufactured by Hexion Co, LTD., now Momentive Specialty Chemicals, Inc.). A photoresist pattern was formed by an exposure process using a KrF lamp and a developing process. A polymer including 0.1 g of polyvinyl pyrrolidone was dissolved in water to form an over-coating composition. The over-coating composition was coated on the metal nitride layer and the photoresist pattern by a spin-on method to form an over-coating layer. The over-coating layer was washed using ethanol and a capping layer having a thickness of about 20 nm was observed to be formed on the photoresist pattern. The metal nitride layer was partially etched using the photoresist pattern and the capping layer as an etching mask to form a metal pattern. An etching solution including 0.1% by weight of hydrogen peroxide was used for etching the metal nitride layer. The capping layer and the photoresist pattern were removed by a strip process.

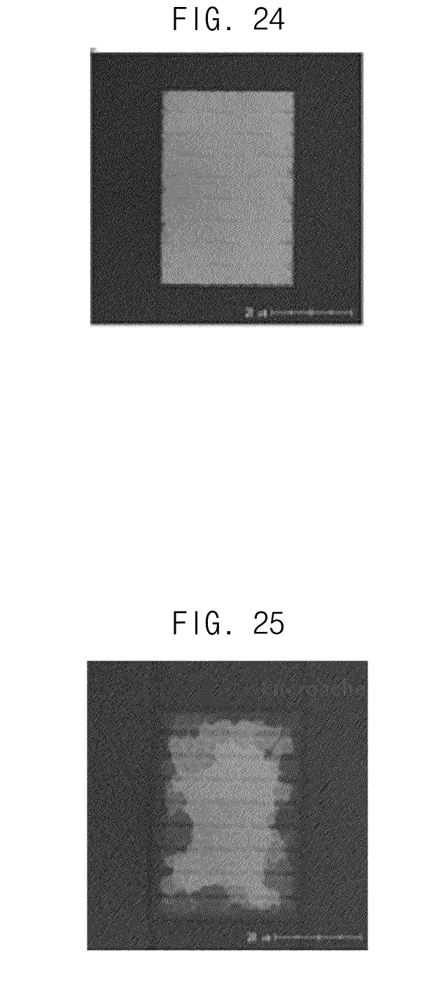

FIG. 24 is a TEM image showing the metal (nitride) pattern formed in accordance with this Example. Specifically, FIG. 24 shows a top surface of the metal (nitride) pattern after removing the photoresist pattern and the capping layer by the strip process.

As shown in FIG. 24, a metal (nitride) pattern having cross-sections without damage to peripheral portions was obtained.

### Comparative Example

A metal nitride layer having a thickness of about 1000 Å was formed on a silicon wafer using titanium nitride. A photoresist layer was formed on the metal nitride layer using a commercially available photoresist composition (epoxy novolac manufactured by Hexion Co, LTD., now Momentive Specialty Chemicals, Inc.). A photoresist pattern was then formed by an exposure process using a KrF lamp and a developing process. Next, the metal nitride layer was partially etched using the photoresist pattern as an etching mask to form a metal nitride pattern. An etching solution including 0.1% by weight of hydrogen peroxide was then used for etching the metal nitride layer. Finally, the photoresist pattern was removed by a strip process.

FIG. 25 is a TEM image showing the titanium nitride pattern formed in accordance with this Comparative Example. Specifically, FIG. 25 shows a top surface of the titanium nitride pattern after removing the photoresist pattern by the strip process.

As shown in FIG. 25, edge portions or peripheral portions of the titanium nitride pattern were damaged by the etching solution. That is, it is acknowledged that the peripheral portions beneath the photoresist pattern was partially removed or damaged during the etching process for forming the titanium nitride pattern.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses, if present, are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of forming a metal or metal nitride pattern, comprising:
forming a metal or metal nitride layer on a substrate;
forming a photoresist pattern on the metal or metal nitride layer;
coating an over-coating composition on the metal or metal nitride layer and on the photoresist pattern to form a capping layer on the photoresist pattern, the over-coating composition including a polymer and a solvent, the polymer having amine groups as a side chain or a branch;
removing a remaining portion of the over-coating composition by washing with a hydrophilic solution; and
partially removing the metal or metal nitride layer using the capping layer and the photoresist pattern as an etching mask.

2. The method of claim 1, wherein the polymer included in the over-coating composition is produced by a single-polymerization or a co-polymerization of at least one monomer selected from the group consisting of vinyl pyrrolidone, vinyl caprolactam, vinyl imidazole, vinyl piperidine and vinyl pyrrolidine.

3. The method of claim 1, wherein forming the photoresist pattern includes:
forming a photoresist layer using a photosensitive polymer on the metal or metal nitride layer; and
partially removing the photoresist layer by an exposure process,
wherein a photoresist residue remains on a portion of the metal or metal nitride layer not covered by the photoresist pattern.

4. The method of claim 3, wherein the photosensitive polymer includes carboxylic groups as a side chain or a branch.

5. The method of claim 4, wherein the over-coating composition further includes a pH adjusting agent, and wherein the pH value of the over-coating composition is within a range of about 4 to about 6.

6. The method of claim 5, wherein the polymer of the over-coating composition and the photosensitive polymer are combined with each other by forming an ionic bond.

7. The method of claim 3, further comprising combining the polymer of the over-coating composition with the photosensitive polymer by forming a hydrogen bond or a dipole interaction.

8. The method of claim 3, wherein the photoresist residue is removed by the hydrophilic solution together with the over-coating composition.

9. The method of claim 1, wherein the metal or metal nitride layer is formed of at least one selected from the group consisting of titanium, titanium nitride, aluminum, aluminum nitride, tungsten and tungsten nitride.

10. The method of claim 1, wherein the hydrophilic solution includes water or alcohol.

11. The method of claim 1, wherein partially removing the metal or metal nitride layer includes performing a wet etching process using a hydrogen peroxide solution.

12. The method of claim 1, wherein the over-coating composition further includes a thermal acid generator.

13. The method of claim 12, further comprising performing a baking process on the capping layer.

14. A method of manufacturing a semiconductor device, comprising:
forming a gate pattern on a substrate;
forming impurity regions at upper portions of the substrate adjacent to the gate pattern;
forming an insulating interlayer covering the substrate and the gate pattern;
forming plugs through the insulating interlayer, the plugs being electrically connected to the impurity regions;
forming a metal or metal nitride layer on the insulating interlayer and on the plugs;
forming a photoresist pattern on the metal or metal nitride layer;
coating an over-coating composition on the metal or metal nitride layer and on the photoresist pattern to form a capping layer on the photoresist pattern, the over-coating composition including a polymer and a solvent, the polymer having amine groups as a side chain or a branch;
removing a remaining portion of the over-coating composition by washing with a hydrophilic solution; and
partially removing the metal or metal nitride layer using the capping layer and the photoresist pattern as an etching mask to form metal wirings electrically connected to the plugs.

15. The method of claim 14, wherein forming the gate pattern includes:
forming a gate insulation layer and a gate electrode layer sequentially on the substrate;
forming a photoresist pattern on the gate electrode layer;
coating an over-coating composition on the gate electrode layer and on the photoresist pattern to form a capping layer on the photoresist pattern, the over-coating composition including a polymer and a solvent, the polymer having amine groups as a side chain or a branch;
removing a remaining portion of the over-coating composition by washing with a hydrophilic solution;
partially removing the gate electrode layer using the capping layer and the photoresist pattern as an etching mask to form a gate electrode; and
partially removing the gate insulation layer using the gate electrode as an etching mask to form a gate insulation layer pattern.
